(19) United States
(12) Patent Application Publication
(10) Pub. No.: US 2005/0225211 A1
(43) Pub. Date: Oct. 13, 2005

(54) Matching layer systems and methods for ultrasound transducers

(75) Inventor: Nelson H. Oliver, Sunnyvale, CA (US)

Correspondence Address: Siemens Corporation;Intellectual Property Department, 170 Wood Avenue South, Iselin, NJ, 08830, US

(73) Assignee: Siemens Medical Solutions USA, Inc.

(21) Appl. No.: 10/816,299

(22) Filed: Apr. 1, 2004

(51) Int. Cl. H01L 41/08

(52) U.S. Cl. 310/334

(57) ABSTRACT

Castable matching layers having a desired acoustic impedance are formed with hafnium compounds. For example, a low sound velocity matching layer with an acoustic impedance of about 5 MRayl is formed by mixing hafnia (HfO₂) powder with a casting resin. The matching layer is used for low frequency operation, such as operation at four or fewer megahertz, while providing a matching layer with a thickness of 150 microns or less for easy dicing. Since a maximum dicing blade exposure to blade thickness ratio is about 30 to 1, higher velocity matching layers may lead to dicing depths requiring thicker dicing blades. By using hafnium compounds, a lesser thickness may be provided, avoiding a reduction in sensitivity and mechanical stability due to wider kerfs resulting from thicker dicing blades. Other thicknesses, frequencies, acoustic impedances or other characteristics may be provided.

### BACKGROUND

The present invention relates to matching layers for ultrasound transducers. In particular, the density of a filled-resin matching layer is controlled by the selection of filler compound.

Ultrasound transducers, such as piezoelectric ceramics, are acoustically mismatched from tissue. To provide a gradual change in acoustic impedance, matching layers are positioned between the transducer and tissue. Any number of matching layers may be provided, such as one or two or more. Three matching layers are commonly used. Each matching layer has a different density or acoustic impedance, such as having a greater density for a matching layer adjacent to a transducer and a lesser density for a matching layer adjacent to tissue.

Different fillers may provide different densities and associated acoustic impedances. For example, glass microspheres, silico-aluminate ceramic or tungsten carbide fillers are used. However, the mechanical characteristics of fillers may result in difficulty in manufacture. For example, tungsten carbide fillers may be used for matching layers with an acoustic impedance of 5 MRayl or higher. However, tungsten carbide has variable density and is difficult to cut. Since matching layers are typically diced with transducer material, the tungsten carbide filler may reduce the lifetime of the dicing blade. The variable density may result in a greater variability of the acoustic impedance of the matching layer. Tungsten carbide is expensive for the particle sizes used in a matching layer.

Zeolite silico-aluminate microspheres have been loaded into a casting resin to provide a higher sound velocity than the unfilled resin for a matching layer. Zeolite microspheres provide a high velocity matching layer compound for use with high frequency transducers, such as greater than 10 Megahertz, because Zeolite microspheres result in matching layers with a thickness greater than 75 microns.

### BRIEF SUMMARY

By way of introduction, the preferred embodiments described below include methods and systems for acoustic matching of ultrasound transducers. Castable matching layers having a desired acoustic impedance are formed with hafnium compounds. For example, a low sound velocity matching layer with an acoustic impedance of about 5 MRayl is formed by mixing hafnia (hafnium oxide, HfO₂) powder with a casting resin. The matching layer is used for low frequency operation, such as operation at four or fewer megahertz, while providing a matching layer with a thickness of 150 microns or less for easy dicing. Since a maximum dicing blade exposure to blade thickness ratio is about 30 to 1, higher velocity matching layers may lead to dicing depths requiring thicker dicing blades. By using hafnium compounds, a lesser thickness may be provided, avoiding a reduction in sensitivity and mechanical stability due to wider kerfs that result from thicker dicing blades. Other thicknesses, frequencies, acoustic impedances or other characteristics may be provided.

In a first aspect, an improvement in a matching layer of an ultrasound transducer is provided. The matching layer includes a castable, curable resin. The improvement is a hafnia filler.

In a second aspect, a method is provided of manufacturing an ultrasound transducer with acoustic matching. A resin is loaded with a hafnium compound. The resin loaded with the hafnium compound is cast. The cast material is positioned as a matching layer on the ultrasound transducer.

In a third aspect, an ultrasound transducer is provided for acoustic use adjacent to tissue. An acoustic impedance matching layer is positioned adjacent to a transducer element. The matching layer includes a hafnium compound.

The present invention is defined by the following claims, and nothing in this section should be taken as a limitation on those claims. Further aspects and advantages of the invention are discussed below in conjunction with the preferred embodiments and may be later claimed independently or in combination.

### BRIEF DESCRIPTION OF THE DRAWINGS

The components and the figures are not necessarily to scale, emphasis instead being placed upon illustrating the principles of the invention. Moreover, in the figures, like reference numerals designate corresponding parts throughout the different views.

FIG. 1 is a cross-sectional diagram of one embodiment of an ultrasound transducer with a hafnia based matching layer; and

FIG. 2 is a flow chart diagram of one embodiment of a method for manufacturing an ultrasound transducer with acoustic matching.

### DETAILED DESCRIPTION OF THE DRAWINGS AND PRESENTLY PREFERRED EMBODIMENTS

A hafnium compound is used as a filler in a castable matching layer to minimize the sound of speed for a given acoustic impedance as compared to other fillers. For example, an about 5 MRayl matching layer is provided with a relatively low speed of sound. By minimizing the sound of speed within a matching layer of a given acoustic impedance, a thinner matching layer may be provided, such as for use on a lower frequency transducer. In alternative embodiments, a hafnium compound is used for higher frequency transducers, different acoustic impedance matching layers, or for providing different relative speeds.

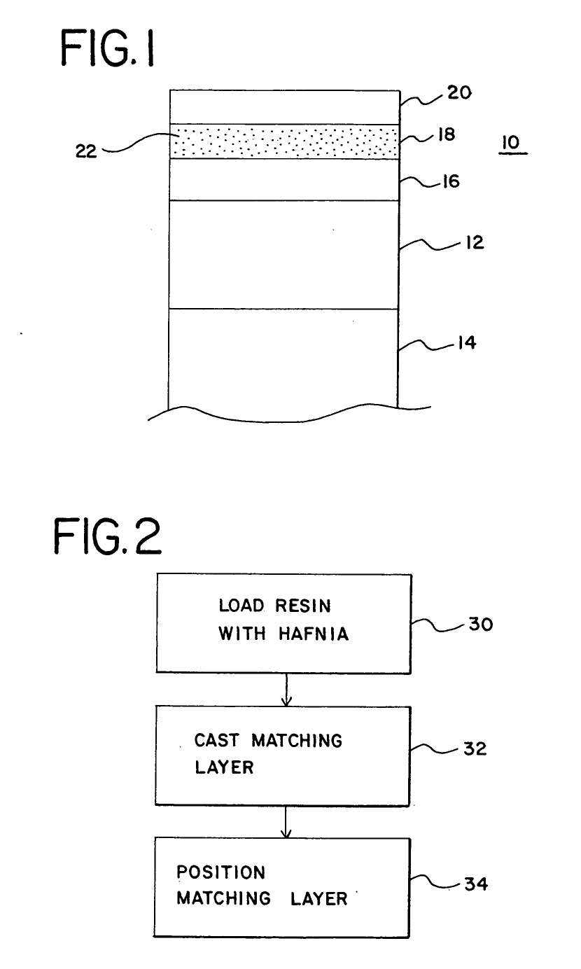

FIG. 1 shows one embodiment of an ultrasound transducer 10 for acoustic use adjacent to tissue. The transducer 10 includes a transducer element 12, a backing block 14, and three acoustic impedance matching layers 16, 18 and 20. Additional, different or fewer components may be provided, such as using only one, only two or four or more matching layers, or matching layer(s) displaying a uniformly graded impedance. In one embodiment, the ultrasound transducer 10 is a low frequency cardiac transducer, such as intended for use at less than 4, 3, or 2 Megahertz, or other frequencies.

The transducer element 12 is a piezoelectric, capacitive membrane or other now known or later developed structure for transducing between acoustic and electrical energies. The transducer element 12 corresponds to a single element within a multi-element array or is a slab of material for later dicing to form individual elements of an array. The transducer element 12 shown in FIG. 1 has a uniform thickness, but non-uniform thicknesses may be provided, such as a concave or convex thickness that varies as a function of elevation and/or azimuth position.

The backing block 14 is a resin or other material for absorbing acoustic energy while minimizing unwanted acoustic reflections. The backing block 14 may be a structural support for the transducer element 14. The backing block 14 acts to prevent undesired echoes from acoustic energy transmitted away from a patient from being received during imaging of a patient.

The acoustic matching layers 16, 18 and 20 are positioned adjacent to the transducer element 12, such as being stacked on top of the transducer element 12. The acoustic impedance matching layers 16, 18 and 20 are formed from the same or different materials. For example each of the acoustic matching layers 16, 18 and 20 include a same resin, but different filler materials. Alternatively, different resins are used for one or more of the matching layers 16, 18 and 20 or a same filler material is used for more than one of the matching layers 16, 18 and 20. Any now known or later developed acoustic matching layers may be provided. Uniform or variable density matching layers may be used.

One of the matching layers, such as the intermediate matching layer 18, includes a hafnium filler, such as hafnia, represented at 22. The matching layer 18 with the hafnia filler 22 is an intermediate matching layer positioned between an upper matching layer 20 and a lower matching layer 16. The relative positioning of the matching layers provides a stepwise gradual shift in acoustic impedance from the acoustic impedance of the transducer element 12 to an acoustic impedance of tissue, gel or other acoustic impedance. Additional or different matching layers 16, 18 and 20 may include hafnium compounds with or without other fillers.

The matching layer 18 includes a resin. In one embodiment, the resin is an epoxy. Other now known or later developed resins may be used. As shown in FIG. 1 as part of a transducer stack, the resin is cured in a cast form. Prior to curing, the resin is gelatinous, liquid, semisolid, plasma, transitional or other form.

The hafnium filler 22 is a hafnium compound, such as hafnia, another hafnium oxide, hafnium carbide, hafnium nitride, hafnium phosphide, or other now known or later developed hafnium compounds. In one embodiment, the hafnia filler 22 is in a powder form. Hafnia powder is non-hazardous, inert, refractory, dense (9.8 g/cm³) and relatively inexpensive as compared to reagent-grade tungsten carbide. Hafnia powder is free flowing powder that is substantially uniform and substantially unvarying in properties such as density. Hafnia composites are easier to grind and dice than the resins because of their friability and resistance to localized melting or smearing.

Hafnia particles of less than 7 microns in a maximum dimension are provided, but greater or lesser sizes may be used. The particle size is selected to provide a desired thickness of the matching layer 18 throughout a range of densities in the matching layer with a strip acoustic impedance of 3 to 8 MRayls. Particle size affects composite density by limiting the maximum practical loading and therefore the maximum density and impedance of the composite. By seeking to formulate composites with filler loadings near the practical maximum, materials are provided that do not tend to settle, or develop other unwanted gradients in constituent concentrations and therefore density. For example, hafnia particles of less than one micron are used for lower loadings (˜20% V/V) or densities and associated acoustic impedances, and larger particle sizes, such as greater than 5 microns, are provided for higher loadings (˜40% V/V) and densities, and thereby their associated acoustic impedances. Using particles less than one micron may allow for an acoustic impedance of about 4 MRayl or less. Using particle sizes greater than 5 microns may allow for acoustic impedances greater than about 6 MRayl. In one embodiment, particles sizes of 3 to 5 microns are provided for a matching layer with an acoustic impedance of about 5 MRayl. Any range of particle sizes may be used. Alternatively, particle sizes within multiple different ranges may be used.

To provide the desired acoustic impedance, the selected hafnia filler 22 is loaded into a casting resin at a desired percentage by volume or weight of the matching layer 18 or matching layer mix. For example, hafnia filler 22 is 10 to 40 percent by volume of the matching layer 18 or matching layer mix. As another example, the hafnia filler 22 is 15 to 25 percent by volume of the matching layer 18 or matching mix. As yet a further example, the hafnia filler 22 is about 20 percent by volume of the matching layer 18 or matching layer mix. In addition to the resin and filler, other agents may be included within the mix, such as dispersing agent (e.g. detergent) and/or defoaming agent. A casting resin loaded with hafnia filler 22 may yield a very dense, very slow composite with a net acoustic impedance within a desired range, such as an acoustic impedance of about 5 MRayl.

The matching layer 18 with the hafnia filler 22 has an ultrasound strip velocity of about 1,600 to 1,900 meters per second, but greater or lesser ultrasound velocities may be provided. In one embodiment, the matching layer 18 has an ultrasound strip velocity of about 1,750 meters per second. The relatively low speed associated with hafnia filled resin reduces the required dicing depth, such as providing for a 5 MRayl matching layer having a thickness of less than 150 microns. Other thicknesses may be provided, such as less than 75 microns or greater than 150 microns. A thickness of less than 150 microns may allow for dicing with dicing blades that are narrow enough to provide for mechanical stability and maximum sensitivity of the transducer elements.

The resin with the hafnia filler 22 is a castable material in one embodiment, such as being a liquid, glass phase or transitional phase material. Using the 20 percent by volume hafnia powder discussed above with a resin, a dense and slow castable composite is provided. Once cured, the resin with hafnia filler is a cast composite of solid, semisolid, glass or transitional phase material.

FIG. 2 shows a method of manufacturing an ultrasound transducer with acoustic matching layer(s) using a resin and hafnia filler or hafnium compound. Different, additional or fewer acts may be provided in the same or different order than shown in FIG. 2. The method shown is for forming one-dimensional, two-dimensional, multi-dimensional or any other now known or later developed transducer array geometries for medical diagnostic ultrasound imaging. For example, a low frequency transducer array is formed with matching layer. As another example, a cardiac transducer array is formed with a matching layer.

In act 30, a resin is loaded with hafnia filler. For example, a hafnia powder is loaded at about 10 to 40 percent, 15 to 25 percent or about 20 percent by volume of a mix. Additional materials may be loaded, such as dispersing agents, other fillers or defoaming agents. Loading is performed by mixing the components together. Any of now known or later developed mixing or loading processes may be used. In one embodiment, the loaded resin with hafnia filler is frozen for storage or transport, but may be cast or otherwise processed without freezing.

In act 32, a matching layer is cast. The loaded resin with hafnia filler is cast. For example, a frozen loaded resin is thawed and dispensed as a thick liquid. The matching layer compound is dispensed onto a steel plate, frame or other structure to provide a matching layer with the desired width, length, thickness, and/or curvature. For example, a thickness of less than 150 microns, a width in a millimeter range and a length in a millimeter or centimeter range is dispensed. In one embodiment, the steel plate is shaped, such as having a concave or convex structure for creating one or more concave or convex structures in the cast matching layer. The cast matching layer is then cured, such as by placing in an oven or allowing to cure at room temperature. After curing, the matching layer is ground to provide a flat surface, such as associated with a bottom surface of the matching layer. The top surface of the matching layer is also ground to be flat or allowed to remain in any desired as-cast shape, such as a convex or concave shape.

The cast matching layer filler material comprises only hafnia particles of less than 7 microns along a maximum dimension in one embodiment, for providing a composite displaying an acoustic impedance of about 3 to 8 MRayl. Other particle sizes, including larger particle sizes, may be used. Different acoustic impedances may be provided. The cast material has an ultrasound strip velocity of about 1,600 to 1,900 meters per second, but different acoustic velocities may be provided.

In act 34, the cast materials are positioned as a matching layer on the ultrasound transducer. For example, vias, a frame or other structure is used to align the cast material as the only, or one of a plurality of matching layers on an ultrasound transducer stack. For example, the cast material is positioned between an upper matching layer and a lower matching layer as shown in FIG. 1. Once positioned, the cast material with hafnia filler is bonded to the transducer stack, such as with epoxy bonding. The transducer stack is then diced to form individual elements of an array. The matching layer may be diced as part of the process. Alternatively, the matching layer is positioned on the transducer stack after dicing of the elements.

While the invention has been described above by reference to various embodiments, it should be understood that many changes and modifications can be made without departing from the scope of the invention. It is therefore intended that the foregoing detailed description be regarded as illustrative rather than limiting, and that it be understood that it is the following claims, including all equivalents, that are intended to define the spirit and scope of this invention.

1. In a matching layer of an ultrasound transducer, the matching layer including a resin, an improvement comprising:
a hafnium filler.

2. The improvement of claim 1 wherein the hafnium filler comprises hafnia powder.

3. The improvement of claim 1 wherein the hafnium filler comprises only particles of less than 7 microns maximum dimension and the matching layer has an acoustic impedance of about 3-8 MRayl.

4. The improvement of claim 3 wherein the particles are less than 1 micron and the acoustic impedance is less than about 4 MRayl.

5. The improvement of claim 3 wherein the particles are greater than 5 microns and the acoustic impedance is greater than about 6 MRayl.

6. The improvement of claim 3 wherein the acoustic impedance is about 5 MRayl.

7. The improvement of claim 1 wherein the hafnium filler comprises 10-40% by volume of the matching layer.

8. The improvement of claim 7 wherein the hafnium filler comprises 15-25% by volume of the matching layer.

9. The improvement of claim 1 wherein the matching layer has an ultrasound strip velocity of about 1600-1900 meters per second.

10. The improvement of claim 9 wherein the matching layer has an ultrasound strip velocity of about 1750 meters per second.

11. The improvement of claim 1 further comprising:
the matching layer being an intermediate matching layer between an upper matching layer and a lower matching layer.

12. The improvement of claim 1 wherein the matching layer has a maximum thickness of less than about 150 microns.

13. The improvement of claim 1 wherein the resin with the filler comprises a castable material.

14. A method of manufacturing an ultrasound transducer with acoustic matching, the method comprising:
(a) loading a resin with a hafnium compound;
(b) casting the loaded resin with the hafnium compound; and
(c) positioning the cast material as a matching layer on the ultrasound transducer.

15. The method of claim 14 wherein (a) comprises loading with hafnia powder at about 10-40% by volume.

16. The method of claim 15 wherein (a) comprises loading with hafnia powder at about 15-25% by volume.

17. The method of claim 15 wherein the hafnium compound comprises only hafnia particles of less than 7 microns maximum dimension and that the cast material has an acoustic impedance of about 3-8 MRayl.

18. The method of claim 15 wherein the cast material has an ultrasound strip velocity of about 1600-1900 meters per second.

19. The method of claim 15 wherein (c) comprises positioning the cast material between an upper matching layer and a lower matching layer.

20. An ultrasound transducer for acoustic use adjacent to tissue, the ultrasound transducer comprising:
a transducer element; and
an acoustic impedance matching layer adjacent the transducer element, the matching layer containing a hafnium compound.
